(19) United States
(12) Patent Application Publication
(10) Pub. No.: US 2017/0024162 A1
(43) Pub. Date: Jan. 26, 2017

(54) COMPUTING SYSTEM AND DATA TRANSFERRING METHOD THEREOF

(71) Applicants: SUN-YOUNG LIM, Hwaseong-si (KR); Taeksoo Kim, Suwon-si (KR); Indong Kim, Seongnam-si (KR); Hangu Sohn, Suwon-si (KR)

(72) Inventors: SUN-YOUNG LIM, Hwaseong-si (KR); Taeksoo Kim, Suwon-si (KR); Indong Kim, Seongnam-si (KR); Hangu Sohn, Suwon-si (KR)

(21) Appl. No.: 15/152,029

(22) Filed: May 11, 2016

(30) Foreign Application Priority Data
Jul. 22, 2015 (KR) 10-2015-0103614

(51) Int. Cl. G06F 3/06; G11C 29/52; G06F 11/10

(52) U.S. Cl. CPC G06F 3/0647; G06F 3/0619; G06F 3/0685; G06F 11/1068; G11C 29/52

(57) ABSTRACT

A computing system includes a host, at least one memory module connected with the host through a first channel, and at least one nonvolatile memory module connected with the host through a second channel. The host includes an encoder configured to encode packet data, and a memory module driver configured to transfer the encoded packet data to the at least one memory module when there is no need to decode the encoded packet data and to decode the encoded packet data using a decoder table when there is a need to decode the encoded packet data, the memory module transferring the decoded packet data to the at least one nonvolatile memory module.

### CROSS-REFERENCE TO RELATED APPLICATION

The present application claims under 35 U.S.C. §119 priority to and the benefit of Korean Patent Application No. 10-2015-0103614 filed on Jul. 22, 2015 in the Korean Intellectual Property Office, the entire contents of which are incorporated by reference herein.

### BACKGROUND

1. Technical Field

The present inventive concept relate a computing system and a data transferring method thereof.

2. Description of the Related Art

A nonvolatile memory for various interfaces of an existing computing system is being developed. For example, a flash memory may be designed for both data storage device and main memory (or working memory) on the same slot of a computer system. In this case, the flash memory need to be compatible with a conventional volatile RAM such as DRAM, and thus a technique for maintaining compatibility with the volatile RAM and optimal data integrity is required.

### SUMMARY

Exemplary embodiments of the inventive concept provide a computing system and a data transferring method thereof.

At least one exemplary embodiment of the inventive concepts is directed to provide a computing system. The computing system may include a host, at least one memory module connected with the host through a first channel, and at least one nonvolatile memory module connected with the host through a second channel. The host may include an encoder configured to encode packet data, and a memory module driver configured to transfer the encoded packet data to the at least one memory module when there is no need to decode the encoded packet data and to decode the encoded packet data using a decoder table when there is a need to decode the encoded packet data, the memory module transferring the decoded packet data to the at least one nonvolatile memory module.

The host and the at least one memory module may transmit/receive data with each other through a double data rate (DDR) interface, and the host and the at least one nonvolatile memory module may transmit/receive data with each other through the DDR interface.

The encoder may perform at least one of scrambling, ECC encoding, swizzling, or randomizing with respect to the packet data.

The packet data may include slot information indicating that the at least one memory module and the at least one nonvolatile memory module are inserted, and the memory module driver may determine whether to decode the encoded packet data, based upon the slot information.

The decoder table may be generated using initialization data transferred from the at least one nonvolatile memory module during an initialization operation of the at least one nonvolatile memory module.

The initialization data may be transferred to the host from the at least one nonvolatile memory module by a mode register set (MRS) mode read operation.

A decoder function may be generated using the decoder table.

Data may be updated in a predetermined order on the at least one nonvolatile memory module, and the memory module driver may generate a command table by recognizing the updated data.

The at least one nonvolatile memory module may include a plurality of nonvolatile memories, a buffer memory configured to temporarily store data needed for driving, and a nonvolatile memory module controller configured to control the plurality of nonvolatile memories and the buffer memory. The nonvolatile memory module controller may include a RAM which exchanges data with the host through a DDR interface.

The at least one nonvolatile memory module may include a plurality of nonvolatile memories, data buffers configured to transmit/receive data with the host, a plurality of dynamic random access memories transmitting and receiving data of the data buffers, and a nonvolatile memory module controller configured to control the plurality of nonvolatile memories and the plurality of dynamic random access memories and to enable the host to access the plurality of nonvolatile memories.

The at least one nonvolatile memory module may include a plurality of nonvolatile memories, a plurality of dynamic random access memories exchanging data with the host through a DDR interface, and a nonvolatile memory module controller configured to control the plurality of nonvolatile memories and the plurality of dynamic random access memories and to enable the host to access the plurality of nonvolatile memories.

Another aspect of exemplary embodiments of the inventive concept is directed to provide a data transfer method of a computing system which includes a host, at least one volatile memory module, and at least one nonvolatile memory module, the method including scrambling packet data, determining whether there is a need to descramble the scrambled packet data, descrambling the scrambled packet data using a decoder table when there is a need to descramble the scrambled packet data, and outputting the descrambled packet data to the at least one nonvolatile memory module.

The determining may be performed based upon slot information indicating that the at least one volatile memory module or the at least one nonvolatile memory module is inserted.

The method may further include outputting the scrambled packet data to the at least one volatile memory module when there is no need to descramble the scrambled packet data.

During an initialization operation of the at least one nonvolatile memory module, the decoder table may be generated by transferring predetermined data between the host and the at least one nonvolatile memory module, decoding the transferred data, and comparing the transferred data and the decoded data.

Another aspect of exemplary embodiments of the inventive concept is directed to provide a data transfer method of a computing system which includes a host, at least one volatile memory module, and at least one nonvolatile memory module, the method including descrambling an address, a command, data, or a serial presence detect (SPD) command, scrambling the descrambled address, command, data or SPD command, and transferring the scrambled address, command, data or SPD command to the at least one volatile memory module or the at least one nonvolatile memory module.

The scrambling may include descrambling the address and the command when defining a command between the host and the at least one volatile memory module or between the host and the at least one nonvolatile memory module.

The SPD command may be transferred to the at least one volatile memory module or the at least one nonvolatile memory module through a side-band channel.

The method may further include constructing the address, the command, the data, or the SPD command with a table.

The method may further include changing a descramble manner so as to correspond to a scramble manner.

### BRIEF DESCRIPTION OF THE DRAWINGS

The above and other objects and features will become apparent from the following description with reference to the following figures, wherein like reference numerals refer to like parts throughout the various figures unless otherwise specified.

FIG. 1 is a diagram illustrating a computing system according to an exemplary embodiment of the inventive concept.

FIG. 2 is a diagram illustrating a method for generating a decoder table, according to an exemplary embodiment of the inventive concept.

FIG. 3 is a flow chart illustrating a command table generating method according to an exemplary embodiment of the inventive concept.

FIG. 4 is a flow chart illustrating a data write method of a computing system according to an exemplary embodiment of the inventive concept.

FIG. 5 is a flow chart illustrating a data read method of a computing system according to an exemplary embodiment of the inventive concept.

FIG. 6 is a block diagram illustrating a server system according to another exemplary embodiment of the inventive concept.

FIG. 7 is a diagram illustrating a computing system according to an exemplary embodiment of the inventive concept.

FIG. 8 is a diagram illustrating a computing system according to an exemplary embodiment of the inventive concept.

FIG. 9 is a block diagram illustrating a data transfer method of a computing system 40 illustrated in FIG. 8.

FIG. 10 is a block diagram illustrating a computing system according to an exemplary embodiment of the inventive concept.

FIG. 13 is a block diagram illustrating one of nonvolatile memory modules of FIG. 10, according to an exemplary embodiment of the inventive concept.

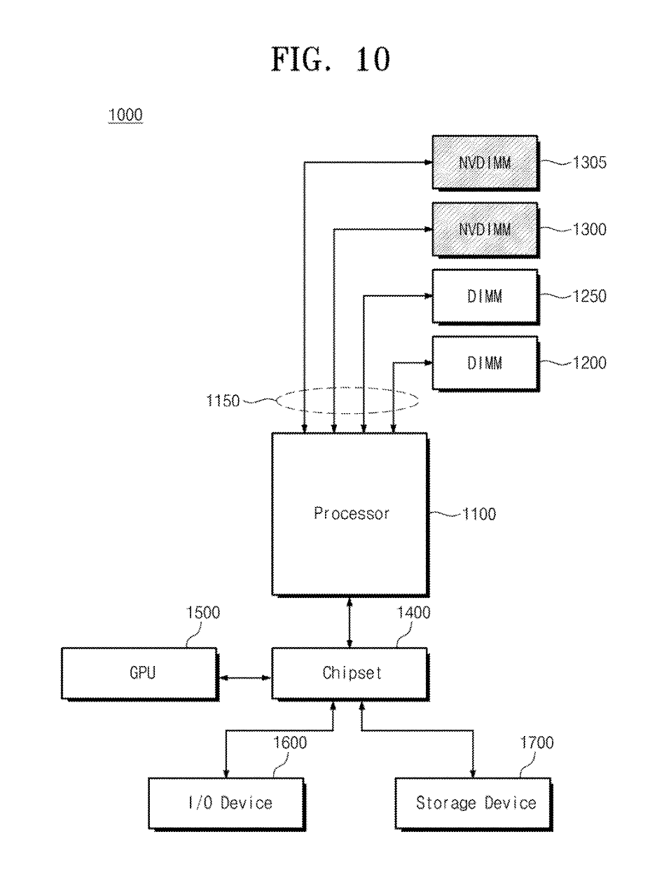

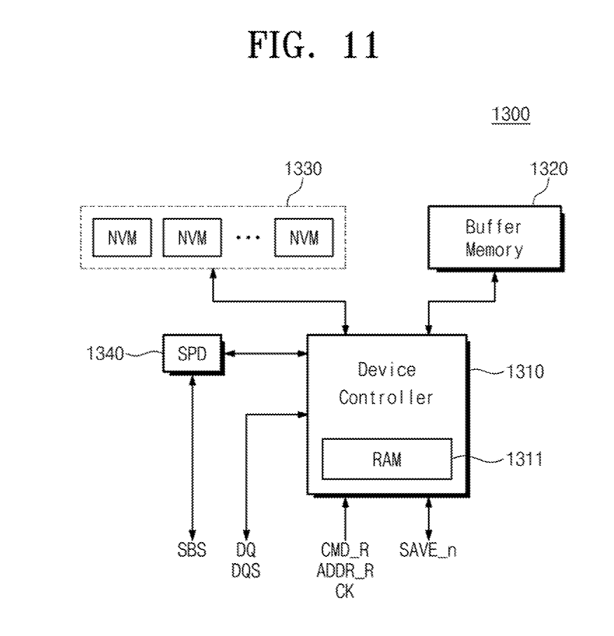

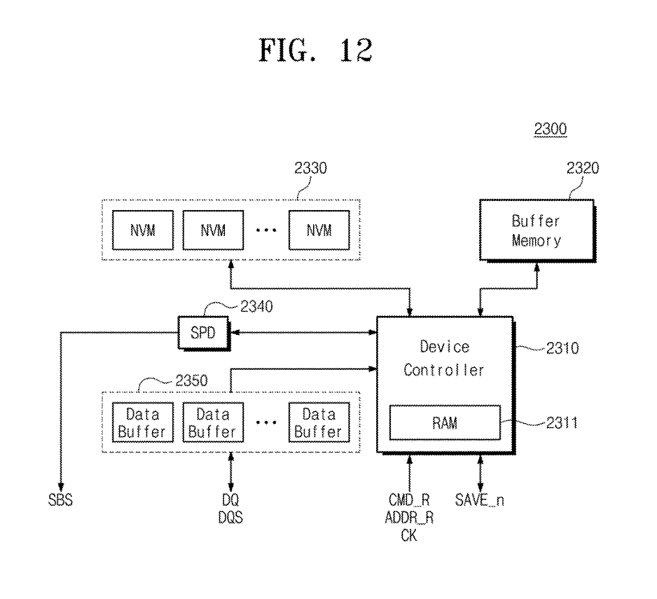

FIG. 12 is a block diagram illustrating one of nonvolatile memory modules of FIG. 10, according to an exemplary embodiment of the inventive concept.

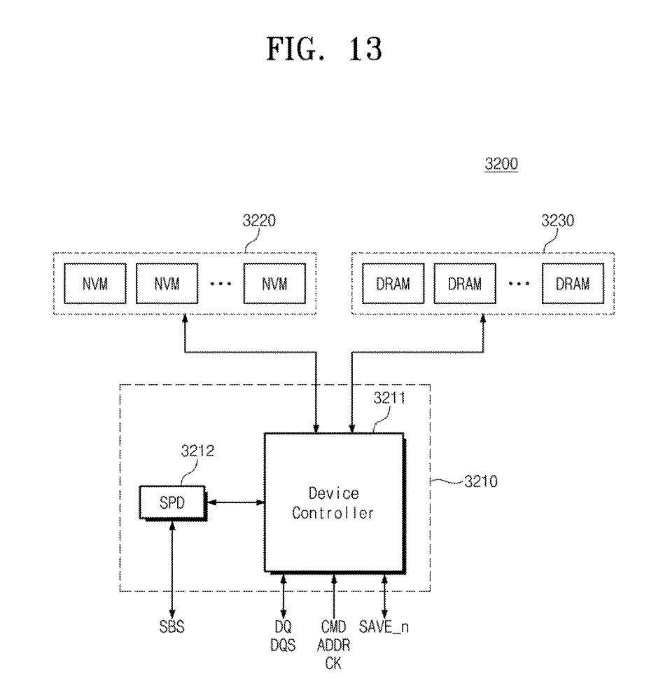

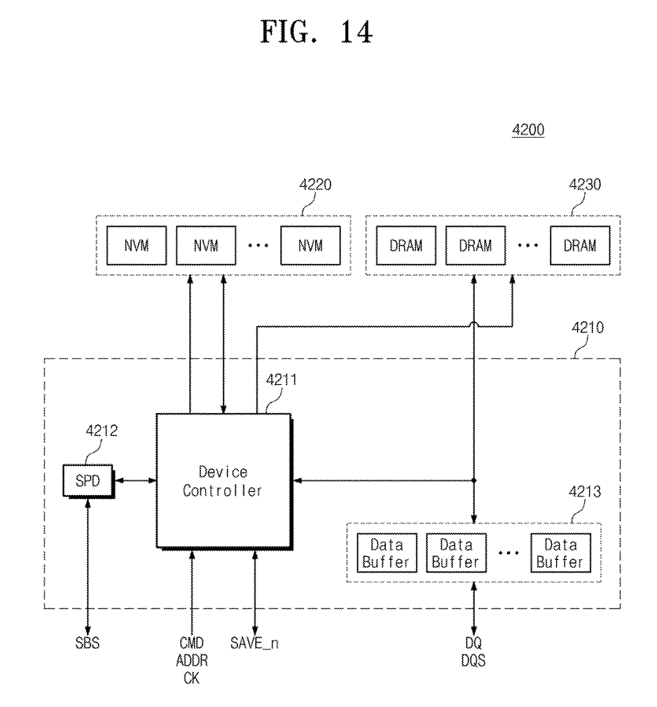

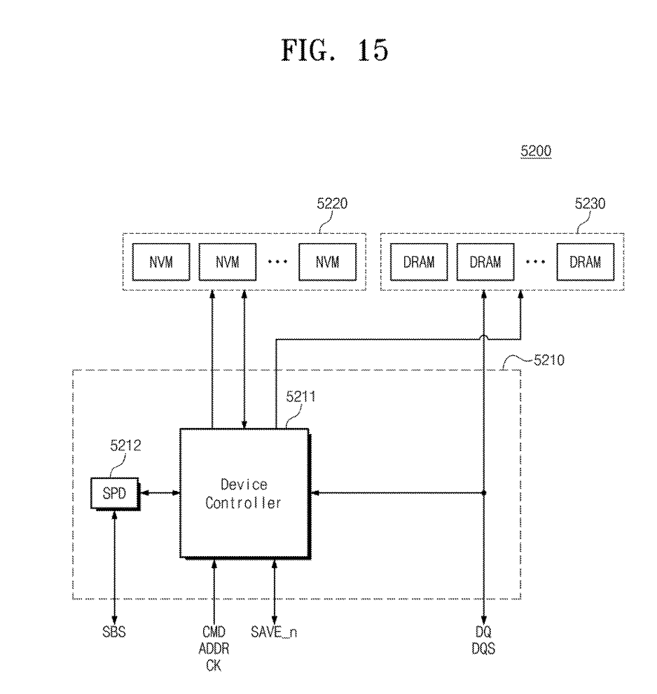

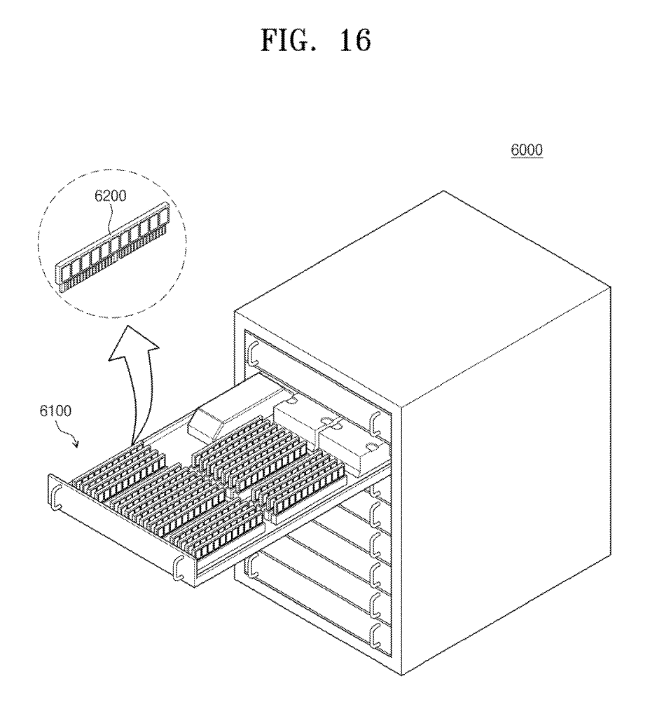

FIG. 13 is a block diagram illustrating one of nonvolatile memory modules of FIG. 10, according to an exemplary embodiment of the inventive concept.

FIG. 14 is a block diagram illustrating one of nonvolatile memory modules of FIG. 10, according to an exemplary embodiment of the inventive concept.

FIG. 15 is a block diagram illustrating one of nonvolatile memory modules of FIG. 10, according to an exemplary embodiment of the inventive concept.

FIG. 16 is a diagram illustrating a server system to which a nonvolatile memory system according to an exemplary embodiment of the inventive concept is applied.

### DETAILED DESCRIPTION

Exemplary embodiments will be described in detail with reference to the accompanying drawings. The inventive concept, however, may be embodied in various different forms, and should not be construed as being limited only to the illustrated exemplary embodiments.

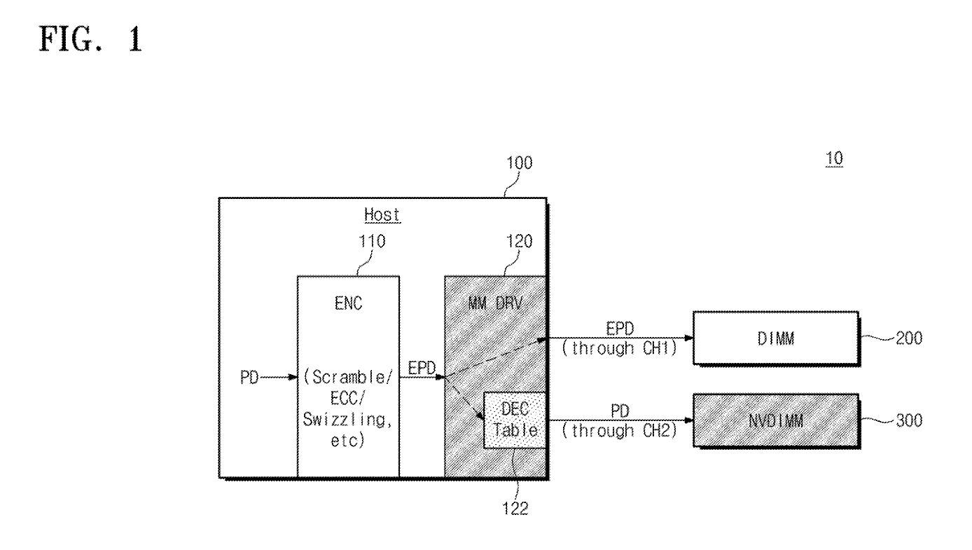

FIG. 1 is a diagram illustrating a computing system 10 according to an exemplary embodiment of the inventive concept. Referring to FIG. 1, a computing system 10 may include a host 100, at least one memory module 200, and at least one nonvolatile memory module 300.

The computing system 10 may be used as a computer, a portable computer, a ultra-mobile personal computer (UMPS), a workstation, a data server, a net book, a personal data assistant (PDA), a portable multimedia player (PMP), a digital camera, a digital audio recorder/player, a digital camera/video recorder/player, a portable game machine, a navigation system, a black box, a 3D television, a device capable of transmitting and receiving information in a wireless environment, one of various electronic devices constituting a home network, one of various electronic devices constituting a computer network, one of various electronic devices constituting a telematics network, radio-frequency identification (RFID), or one of various electronic devices constituting a computing system.

The host 100 may include an encoder 110 and a memory module driver (MM DRV) 120. For example, the host 100 may be at least one processor, a central processing unit (CPU), a graphic processing unit (GPU), and the like.

The encoder 110 may encode packet data PD. Encoding may be performed using at least one of scrambling, error correction code (ECC) encoding, swizzling, or randomizing.

The memory module driver 120 may allow the host 100 to access the memory module 200 and the nonvolatile memory module 300 with a DRAM-based double data rate (DDR) interface. The memory module driver 120 may be implemented with hardware, software and/or firmware.

The memory module driver 120 may be connected with the memory module 200 through a first channel CH1 and with the nonvolatile memory module 300 through the second channel CH2. The first and second channels CH1, CH2 may include physical slots which are different from each other.

When packet data PD is data to be transferred to the memory module 200, the memory module driver 120 may transfer encoded packet data EPD, which is encoded by the encoder 100, to the memory module 200 through the first channel CH1. The packet data PD may include slot information indicating that the memory module 200 and the nonvolatile memory module 300 are inserted.

When packet data PD is data to be transferred to the nonvolatile memory module 300, the memory module driver 120 may transfer data, which is obtained by decoding the encoded packet data EPD encoded by the encoder 100. In other words, original data PD may be transferred to the nonvolatile memory module 300 through the second channel CH2.

For clear and concise description, it may be assumed that the host 100 has information about whether a device inserted into a physical slot is the memory module 200 or the nonvolatile memory module 300. When generating the packet data PD, the host 100 may add information corresponding to a slot to the packet data PD, and the memory module driver 120 may determine whether the encoded packet data EPD is decoded, based upon the slot information.

In particular, the memory module driver 120 may include a decoder table 122 for decoding encoded packet data. In an exemplary embodiment, the decoder table 122 may be a previously stored value. In another exemplary embodiment, the decoder table 122 may be determined by performing a defined communication between the host 100 and the nonvolatile memory module 300.

The computing system 10 may perform encoding with respect to data to be stored in the memory module 200 and may not perform encoding with respect to data to be stored in the nonvolatile memory module 300. Though the exemplary embodiment described above includes a decoder, the nonvolatile memory module 300 may not include a decoder for decoding encoded packet data.

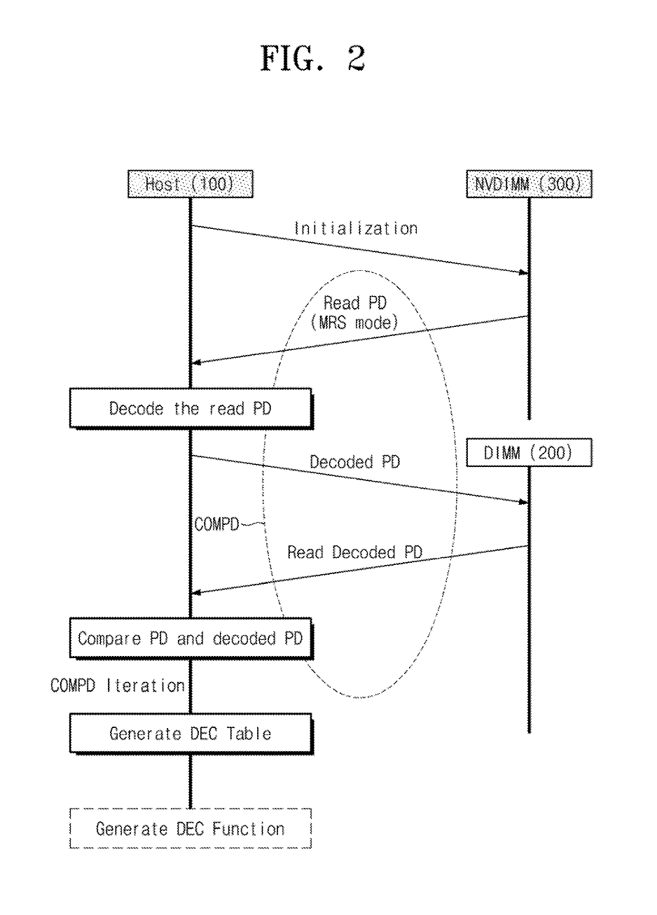

FIG. 2 is a diagram illustrating a method for generating a decoder table, according to an exemplary embodiment of the inventive concept. The nonvolatile memory module 120 of the host 100 may generate a decoder table during an initialization operation of the nonvolatile memory module 300.

The decoder table may be generated during a process to recognize the memory module 300. For example, when the nonvolatile memory module 300 is inserted into a slot, the host 100 may transfer an initialization command to the nonvolatile memory module 300.

The nonvolatile memory module 300 may transfer predetermined initialization packet data to the host 100 in response to the initialization command. The predetermined initialization packet data may be stored in an address area which the host 100 recognizes during the initialization operation. A packet transfer may be a read operation of the host 100 which is performed in a mode register set (MRS) mode. The host 100 may decode read packet data and may transfer the decoded packet data to the memory module 200. The host 100 may read the decoded packet data from the memory module 200. The memory module driver 120 may compare packet data PD read from the nonvolatile memory module 300 and the decoded packet data read from the memory module 200. The above-described procedure may be a packet data comparison procedure COMPD.

It should be understood that with regard to the packet data comparison procedure COMPD of the host 100, a read operation about the nonvolatile memory module 300 is not limited to the MRS mode. With regard to the packet data comparison procedure COMPD, the read operation about the nonvolatile memory module 300 may be any kind of read operation to which encoding and/or decoding is not applied.

The decoder table 122 may be generated by repeating the above-described packet data comparison procedure COMPD several times. Thereafter, a decoder function may be generated using the decoder table 122.

An exemplary embodiment of the inventive concept is illustrated in FIG. 2, where decoded packet data is stored in the memory module 200 in the packet data comparison procedure COMPD. However, the scope and spirit of the inventive concept may not be limited thereto. Decoded packet data may be used for a comparison operation after stored in a part of the host 100, not in the memory module 200.

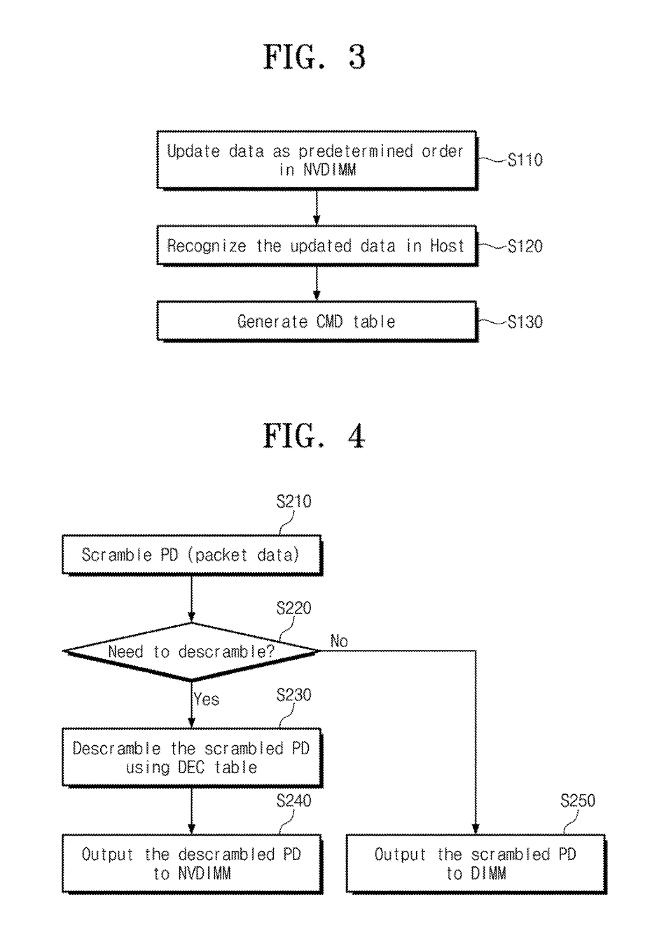

FIG. 3 is a flow chart illustrating a method of command table generating according to an exemplary embodiment of the inventive concept. Hereafter, the method will be described with reference to FIGS. 1 to 3. When generating a specific command, the nonvolatile memory module (NVDIMM) 300 may update data in a predetermined order (S110). The host 100 may recognize updated data sequentially (S120). The specific command to be transferred to the nonvolatile memory module 300 may be generated using the recognized data (S130).

FIG. 4 is a flow chart illustrating a data write method of a computing system according to an exemplary embodiment of the inventive concept. Hereafter, a data write method will be described with reference to FIGS. 1 to 4.

Packet data PD may be scrambled. Typically, scrambling may be performed to increase integrity of transfer data or to reduce power for storing data (S210). The memory module driver 120 may determine whether to descramble scrambled packet data (S220). The determination criteria may be slot information included in the packet data PD.

If descrambling is required, the memory module driver 120 may descramble the scrambled packet data using the decoder table 122. The descrambling may be achieved by generating packet data stored in the nonvolatile memory module 300 through the analysis of the decoder table 122 or generating packet data to be stored in the nonvolatile memory module 300 using the decoder table 122 (or a decoder function) (S230). The memory module driver 120 may transfer the descrambled packet data to the nonvolatile memory module 300 (S240).

If descrambling is not required, the memory module driver 120 may transfer the scrambled packet data to the nonvolatile memory module 200 (S250).

The data write method of the computing system 100 according to an exemplary embodiment of the inventive concept may transfer scrambled packet data to the memory module 200 and may transfer descrambled packet data to the nonvolatile memory module 300.

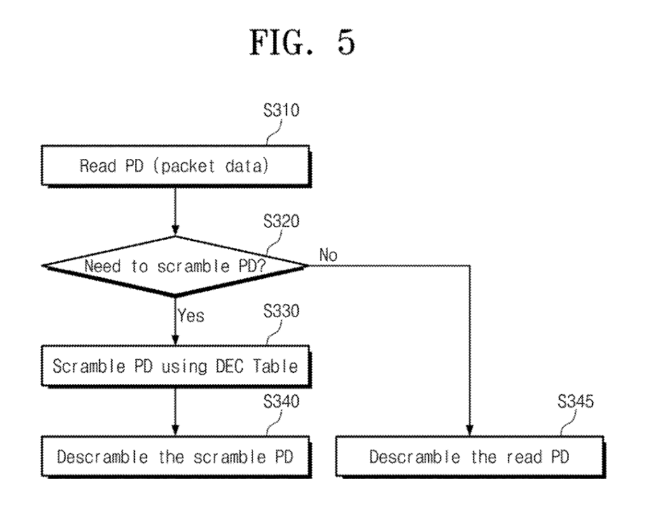

FIG. 5 is a flow chart illustrating a data read method of a computing system according to an exemplary embodiment of the inventive concept. Below, a data read method will be described with reference to FIGS. 1 to 5.

Packet data PD may be read in response to a read request (S310). The memory module driver 120 may determine whether to scramble the read packet data. The determination operation may be performed based upon slot information of the read packet data (S320).

If scrambling is required, the read packet data may be scrambled using the decoder table 122 (S330). Thereafter, the scrambled data may be descrambled (S340). In contrast, if scrambling is not required, the read data may be descrambled (S345).

The data read method of the computing system 100 according to an exemplary embodiment of the inventive concept may immediately descramble data read from the memory module 200 and may first scramble data read from the nonvolatile memory module 300 to then descramble the scrambled data.

In FIGS. 1 to 5, an exemplary embodiment of the inventive concept illustrates that the memory module driver 120 includes the decoder table 120. However, the scope and spirit of the inventive concept may not be limited thereto. A host according to an exemplary embodiment of the inventive concept may be implemented to include a hardware decoder which performs a function of the decoder table 120 illustrated in FIG. 1.

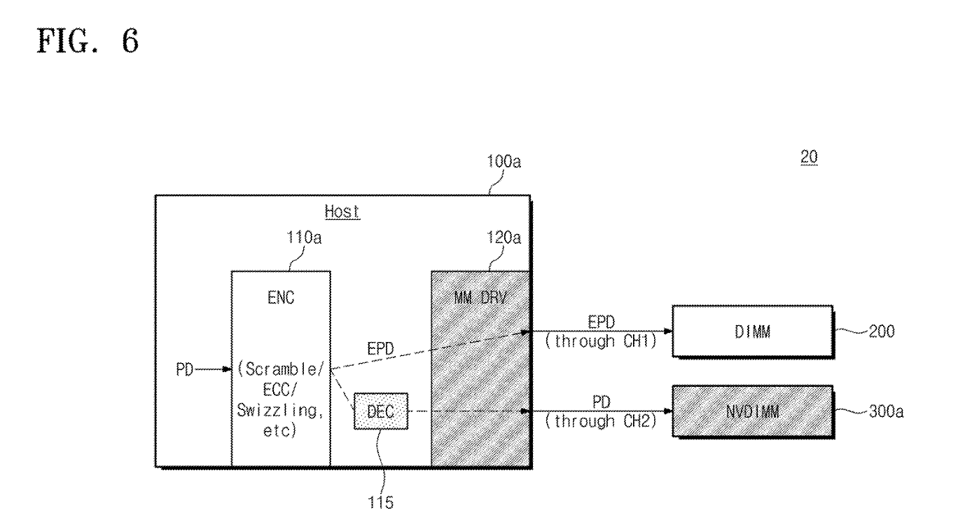

FIG. 6 is a diagram illustrating a computing system 20 according to an exemplary embodiment of the inventive concept. Referring to FIG. 6, a computing system 20 may include a host 100a, at least one memory module 200, and at least one nonvolatile memory module 300a.

The host 100a may include an encoder 110a, a decoder 115, and a memory module driver (MM DRV) 120a. The encoder 110a may encode packet data PD. Encoding may be performed through scrambling, ECC encoding, swizzing, randomizing, or the like. When encoded packet data is data to be stored in the nonvolatile memory module 300a, the decoder 115 may decode the encoded packet data. For data to be stored in the memory module (DIMM) 200, the memory module driver 120a may transfer encoded packet data EPD, outputted from the encoder 110a, to the first channel CH1; for data to be stored in the nonvolatile memory module (NVDIMM) 300a, the memory module driver 120a may transfer decoded packet data PD, outputted from the decoder 115, to the second channel CH2.

In FIGS. 1 to 6, an exemplary embodiment of the inventive concept illustrates that data stored in the nonvolatile memory module NVDIMM is decoded. However, the scope and spirit of the inventive concept may not be limited thereto. The computing system according to an exemplary embodiment of the inventive concept 20 may be implemented to determine whether to perform encoding from the beginning, based upon slot information of packet data PD. For example, data to be stored in the memory module DIMM may be encoded. On the contrary, data to be stored in the nonvolatile memory module NVDIMM may be bypassed.

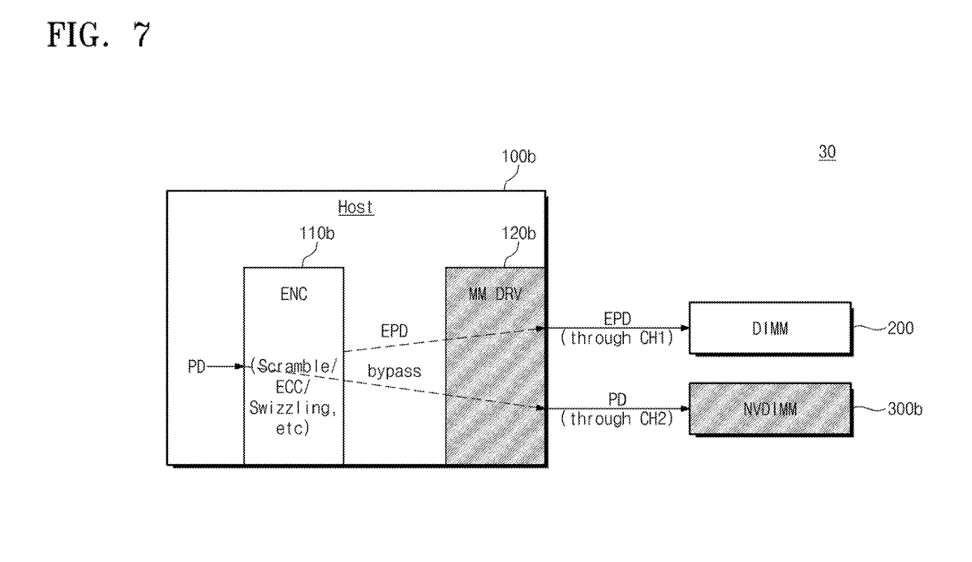

FIG. 7 is a diagram illustrating a computing system 30 according to an exemplary embodiment of the inventive concept. Referring to FIG. 7, a computing system 30 may include a host 100b, at least one memory module 200, and at least one nonvolatile memory module 300b.

Packet data PD may pass through an encoder 110b or may bypass the encoder 110b. For example, when stored in the memory module 200, the packet data PD may be encoded by the encoder 110b. In contrast, when stored in the nonvolatile memory module 300b, the packet data PD may bypass the encoder 110b so as to be directly transferred to the memory module driver 120b.

In FIGS. 1 to 7, an exemplary embodiment of the inventive concept illustrates that encoded packet data EPD is stored in the DIMM 200 and original packet data PD not encoded is stored in the NVDIMM 300/300a/300b. However, the scope and spirit of the inventive concept may not be limited thereto. For example, original data not encoded may be stored in the DIMM, and encoded data may be stored in the NVDIMM.

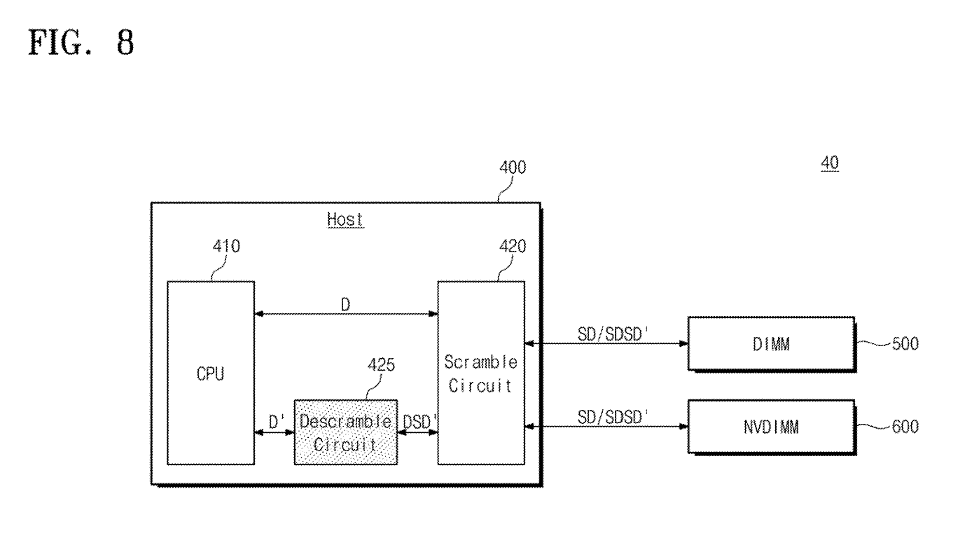

FIG. 8 is a diagram illustrating a computing system 40 according to an exemplary embodiment of the inventive concept. Referring to FIG. 8, a computing system 40 may include a host 400, a DIMM 500, and an NVDIMM 600.

The host 400 may include a CPU 410, a scramble circuit 420, and a descramble circuit 425.

In an exemplary embodiment, the scramble circuit 420 may scramble data D and may output scrambled data SD. In an exemplary embodiment, the scramble circuit 420 may be implemented with software, hardware, and/or firmware.

The descramble circuit 425 may descramble data D′ and may output descrambled data DSD′. Here, descrambling may be an inverted version of scrambling of the scramble circuit 420. In an exemplary embodiment, the descramble circuit 425 may be implemented with software, hardware and/or firmware. The descramble circuit 425 may recognize a scramble method of the scramble circuit 420 and may perform descrambling corresponding to the recognized scramble method.

The descramble circuit 425 may be activated when it transfers a message (e.g., data, a command, or an address), which is not scrambled, to the DIMM 500 or the NVDIMM 600 or to receive a message therefrom.

For example, the descramble circuit 425 may be activated when it transfers a command or an address, which is not scrambled, to define a command with the DIMM 500 or the NVDIMM 600 or to transfer a serial presence detect (SPD) command to be exchanged through a side-band channel (e.g., an I2C communication channel), not a main channel. At this time, the address or data and the SPD data may be constructed with a table, and the data (e.g., table data) thus constructed may be transferred to the DIMM 500 or the NVDIMM 600.

A descrambling function may be added to the descramble circuit 425, or a function of the descramble circuit 425 may be changed according to a scrambling manner of the scramble circuit 420).

The DIMM 500 may exchange scrambled data SD or data SDSD′, obtained by scrambling descrambled data DSD′, with the host 400.

The NVDIMM 600 may exchange scrambled data SD or data SDSD′, obtained by scrambling descrambled data DSD′, with the host 400.

A scramble method may be selectively applied to the DIMM 500 and the NVDIMM 600 according to an exemplary embodiment of the inventive concept.

In the computing system 40 according to an exemplary embodiment of the inventive concept, the DIMM 500 and/or the NVDIMM 600 may not need an additional descramble circuit even though a scramble manner of the host 400 is changed.

The scramble method is described with reference to FIG. 8, but the inventive concept may not be limited thereto. A computing system of the inventive concept may be implemented with any kind of encoder/decoder circuit (e.g., ECC, bit swap, and the like) instead of a scramble/descramble circuit.

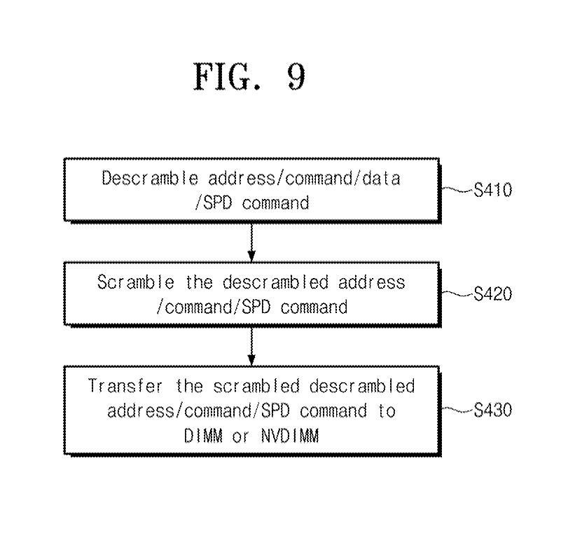

FIG. 9 is a block diagram illustrating a data transfer method of a computing system 40 illustrated in FIG. 8. The data transfer method of the computing system 40 will be described with reference to FIGS. 8 and 9.

An address/command/data/SPD command which does not necessitate scrambling may be descrambled by the descramble circuit 425 (S410). The descrambled address/command/data/SPD command may be scrambled by the scramble circuit 420. The scrambled descramble address/command/data/SPD command may be transferred to the DIMM 500 or the NVDIMM 600 (S430).

In the data transfer method of the computing system 40 according to an exemplary embodiment of the inventive concept, descrambling may be performed when transferring an address/command/data/SPD command not scrambled.

FIG. 10 is a block diagram illustrating a computing system 1000 according to an exemplary embodiment of the inventive concept. Referring to FIG. 10, a computing system 1000 may include a processor 1100, one or more memory modules 1200, 1250, one or more nonvolatile memory modules 1300, 1305, a chipset 1400, a graphic processing unit (GPU) 1500, an input/output device 1600, and a storage device 1700.

The processor 1100 may perform an overall operation of the computing system 1000. The processor 1100 may perform various operations to be executed on the computing system 1000. The processor 1100 may include a memory module driver described with reference to FIGS. 1 to 7, a decoder selectively activated according to slot information, an encoder performing a selective bypass operation based upon the slot information, and scramble and descramble circuits 220, 225 described with reference to FIGS. 8 and 9.

The nonvolatile memory modules 1300, 1305 and the memory modules 1200, 1250 may be directly connected with the processor 1100. For example, each of the nonvolatile memory modules 1300, 1305 and the memory modules 1200, 1250 may have the form of a dual in-line memory module (DIMM). Alternatively, each of the nonvolatile memory modules 1300, 1305 and the memory modules 1200, 1250 may be mounted on a DIMM socket directly to communicate with the processor 1100.

Each of the memory modules 1200, 1250 may be implemented with a memory module 200 or 500 described with reference to FIGS. 1 to 9.

Each of the nonvolatile memory modules 1300, 1305 may be a nonvolatile memory module 300, 300a, or 300b described with reference to FIGS. 1 to 7 or a nonvolatile memory module 600 described with reference to FIGS. 8 and 9.

The nonvolatile memory modules 1300, 1305 and the memory modules 1200, 1250 may communicate with the processor 1100 through the same interface 1150. For example, the nonvolatile memory modules 1300, 1305 and the memory modules 1200, 1250 may communicate with each other through a DDR interface 1150. The processor 1100 may use the memory modules 1200, 1250 as a working memory, a buffer memory, or a cache memory of the computing system 1000.

The chipset 1400 may be electrically connected with the processor 1100 and may control hardware of the computing system 1000 under control of the processor 1100. For example, the chipset 1400 may be connected with each of the GPU 1500, the input/output device 1600, and the storage device 1700 through main buses and may perform a bridge operation with respect to the main buses.

The GPU 1500 may perform a set of arithmetic operations for outputting image data of the computing system 1000. The GPU 1500 may be embedded in the processor 1100 in the form of a system on chip.

The input/output device 1600 may include various devices which receive data or commands from the computing system 1000 or may output data to an external device. For example, the input/output device 1600 may include user input devices such as a keyboard, a keypad, a button, a touch panel, a touch screen, a touch pad, a touch ball, a microphone, a gyroscope sensor, a vibration sensor, a piezoelectric sensor, and the like and user output devices such as a liquid crystal display (LCD), an organic light emitting diode (OLED) display device, an active matrix OLED (AMOLED) display device, a light emitting diode, a speaker, a motor, and the like.

The storage device 1700 may be used as a storage medium of the computing system 1000. The storage device 1700 may include mass storage media such as a hard disk drive (HDD), a solid state drive (SSD), a memory card, a memory stick, and the like.

The nonvolatile memory modules 1300, 1305 may be used as a storage medium of the computing system 1000 through the processor 1100. The interface 1150 between the nonvolatile memory modules 1300, 1305 and the processor 1100 may operate faster in speed than the interface between the storage device 1700 and the processor 1100 does. That is, the processor 1100 may use the nonvolatile memory modules 1300, 1305 as a storage medium, thereby improving the performance of the computing system 1000.

FIG. 11 is a block diagram illustrating one of nonvolatile memory modules of FIG. 10, according to an exemplary embodiment of the inventive concept. FIG. 11 shows a nonvolatile memory module (NVDIMM) 1300 having a protocol of a load reduced DIMM (LRDIMM). The nonvolatile memory module 1300 illustrated in FIG. 11 may be of the form of a dual in-line memory module (DIMM) and may be mounted on a DIMM socket so as to communicate with the processor 1100.

Referring to FIG. 11, the nonvolatile memory module 1300 may include a nonvolatile memory module controller 1310, a buffer memory 1320, a nonvolatile memory device 1330, and a serial presence detect (SPD) chip 1340. The nonvolatile memory module controller 1310 may include a RAM 1311. In an exemplary embodiment, the nonvolatile memory device 1330 may include a plurality of nonvolatile memories NVM. Each of the nonvolatile memories included in the nonvolatile memory device 1330 may be implemented with a chip, a package, a device, or a module. Alternatively, the nonvolatile memory device 1330 may be implemented with a chip or a package.

The nonvolatile memory module controller 1310 may transmit and receive a plurality of data signals DQ and a plurality of data strobe signals DQS to and from the processor 1100 and may receive a RAM command CMD_R, a RAM address ADDR_R, and a clock CK through separate signal lines.

The RAM 1311 may be implemented to transmit/receive data with the host 10100 using data DQ and a data strobe signal DQS based upon a DDR interface or to exchange packet-type data with the buffer memory 1320 and/or the nonvolatile memories through a memory interface. In an exemplary embodiment, the RAM 1311 may be implemented with a volatile/nonvolatile memory device which is randomly accessible at high speed operation. For example, the RAM 1311 may be a dual port SRAM. The memory interface (MEM interface) may be implemented with a SoC-dedicated interface such as AXI (Advanced eXtensible Interface, AXI3, AXI4, and the like), AMBA (Advanced Microcontroller Bus Architecture), OCP (open core protocol), and the like.

The buffer memory 1320 may temporarily store data needed for driving. In an exemplary embodiment, the buffer memory 1320 may store/update metadata and/or a management table for managing the nonvolatile memory device 1330. The buffer memory 1320 may include a random access memory such as DRAM, SRAM, PRAM, MRAM, RRAM, FeRAM, or the like.

The SPD 1340 may be a programmable read only memory device (e.g., EEPROM). The SPD 1340 may include initial information or device information of the nonvolatile memory module 1300. The SPD 1340 may include initial information or device information such as a module type, a module configuration, a storage capacity, an execution environment, and the like of the nonvolatile memory module 1300. When a computing system including the nonvolatile memory module 1300 is booted up, the processor 1100 of the computing system may read the SPD 1340 and may recognize the nonvolatile memory module 1300 based upon the read result. The processor 1100 may use the nonvolatile memory module 1300 as a storage medium based upon the SPD 1340.

The SPD 1340 may communicate with the processor 1100 through a side-band communication channel. The processor 1100 may exchange a side-band signal SBS with the SPD 1340 through the side-band communication channel. The SPD 1340 may communicate with the nonvolatile memory module controller 1310 through the side-band communication channel. In an exemplary embodiment, the side-band communication channel may be an I2C communication based channel. In an exemplary embodiment, the SPD 1340, the nonvolatile memory module controller 1310, and the processor 1100 may communicate with each other through I2C communication or may exchange information through the I2C communication.

FIG. 12 is a block diagram illustrating one of nonvolatile memory modules of FIG. 10, according to another exemplary embodiment of the inventive concept. In an exemplary embodiment, FIG. 12 is a block diagram of a nonvolatile memory module 2300 with a registered DIMM (RDIMM) form. In an exemplary embodiment, the nonvolatile memory module 2300 illustrated in FIG. 12 may be of the form of a dual in-line memory module (DIMM) and may be mounted on a DIMM socket so as to communicate with the processor 1100.

Referring to FIG. 12, the nonvolatile memory module 2300 may include a nonvolatile memory module controller 2310, a buffer memory 2320, a nonvolatile memory device 2330, a serial presence detect (SPD) chip 2340, and a data buffer circuit 2350. The nonvolatile memory module controller 2310 may include a RAM 2311.

The data buffer circuit 2350 may receive information or data from the processor 1100 through a data signal DQ and a data strobe signal DQS and may transfer the received information or data to the nonvolatile memory module controller 2350. Alternatively, the data buffer circuit 2350 may receive information or data from the nonvolatile memory module controller 2310 and may transfer the received information or data to the processor 1100 through a data signal DQ and a data strobe signal DQS.

In an exemplary embodiment, the data buffer circuit 2350 may include a plurality of data buffers. Each of the data buffers may exchange the data signal DQ and the data strobe signal DQS with the processor 1100. Alternatively, each of the data buffers may exchange a signal with the nonvolatile memory module controller 2310. In an exemplary embodiment, each of the data buffers may operate according to control of the nonvolatile memory module controller 2310.

FIG. 13 is a block diagram illustrating one of nonvolatile memory modules of FIG. 10, according to a still another exemplary embodiment of the inventive concept Referring to FIG. 13, the nonvolatile memory module 3200 may include a control circuit 3210, a nonvolatile memory device 3220, and a RAM device 3230. In an exemplary embodiment, the nonvolatile memory device 3220 may include a plurality of nonvolatile memories, and the RAM device 3230 may include a plurality of DRAMs. In an exemplary embodiment, the nonvolatile memories may be used as storage of the computing system 3000 through the processor 1100. In an exemplary embodiment, each of the nonvolatile memories may include nonvolatile memory elements such as an electrically erasable and programmable ROM (EEPROM), a NAND flash memory, a phase-change RAM (PRAM), a resistive RAM (ReRAM), a ferroelectric RAM (FRAM), a spin-torque magnetic RAM (STT-MRAM), and the like.

The DRAMs may be used as a main memory of the computing system 3000 through the processor 1100. In an exemplary embodiment, the RAM device 3230 may include random access memory elements such as a DRAM, an SRAM, an SDRAM, a PRAM, a ReRAM, a FRAM, an MRAM, and the like.

The control circuit 3210 may include a nonvolatile memory module controller 3211 and an SPD 3212. The nonvolatile memory module controller 3211 may receive a command CMD, an address ADDR, and a clock CK from the processor 1100. The nonvolatile memory module controller 3211 may selectively store data, received through the data signal DQ and the data strobe signal DQS, in the nonvolatile memory device 3220 or the RAM device 3230 in response to signals received from the processor 1100. Alternatively, the nonvolatile memory module controller 3211 may selectively transfer data, stored in the nonvolatile memory device 3220 or the RAM device 3230, to the processor 1100 through the data signal DQ and the data strobe signal DQS in response to signals received from the processor 1100.

In an exemplary embodiment, the processor 1100 may selectively access the nonvolatile memory device 3220 or the RAM device 3230 through a command CMD, an address ADDR, or a separate signal or separate information. That is, the processor 1100 may selectively access the nonvolatile memory device 3220 or the RAM device 3230 included in the nonvolatile memory module 3200.

FIG. 14 is a block diagram illustrating one of nonvolatile memory modules of FIG. 10, according to still another exemplary embodiment of the inventive concept. Referring to FIG. 14, the nonvolatile memory module 4200 may include a control circuit 4210, a nonvolatile memory device 4220, and a RAM device 4230. The control circuit 4210 may include a nonvolatile memory module controller 4211, an SPD 4212, and a data buffer circuit 4213.

The nonvolatile memory module controller 4211 may receive a command CMD, an address ADDR, and a clock CK from the processor 1100. The nonvolatile memory module controller 4211 may control the nonvolatile memory device 4220 or the RAM device 4230 in response to received signals. For example, the processor 1100 may selectively access the nonvolatile memory device 4220 or the RAM device 4230. The nonvolatile memory module controller 4231 may control the nonvolatile memory device 4220 or the RAM device 4230 under control of the processor 4100.

The data buffer circuit 4213 may receive the data signal DQ and the data strobe signal DQS from the processor 1100 and may provide the received signals to the device controller 4211 and the RAM device 4230. Alternatively, the data buffer circuit 4213 may provide data, received from the device controller 4211 or the RAM device 4230, to the processor 1100 through the data signal DQ and the data strobe signal DQS.

In an exemplary embodiment, in the case where the processor 1100 stores data in the nonvolatile memory device 4220, data received through the data signal DQ and the data strobe signal DQS may be provided to the device controller 4211, and the nonvolatile memory controller 4211 may process the received data and may provide the processed data to the nonvolatile memory device 4220. Alternatively, in the case where the processor 1100 reads data stored in the nonvolatile memory device 4220, the data buffer circuit 4213 may provide data provided from the nonvolatile memory controller 4211 to the processor 4100 through the data signal DQ and the data strobe signal DQS. In the case where the processor 1100 stores data in the RAM device 4230, data provided to the data buffer circuit 4213 may be provided to the RAM device 4230, and the nonvolatile memory module controller 4231 may transfer received command CMD, addresses ADDR, and clock CK to the RAM device 4230. Alternatively, when the processor 1100 reads data stored in the RAM device 4230, the nonvolatile memory module controller 4231 may transfer the received command CMD, addresses ADDR, and clock CK to the RAM device 4230, and the RAM device 4230 may provide data to the data buffer circuit 4213 in response to the transferred signals. At this time, the data buffer circuit 4213 may provide data to the processor 1100 through the data signal DQ and the data strobe signal DQS.

FIG. 15 is a block diagram illustrating one of nonvolatile memory modules of FIG. 10, according to a further exemplary embodiment of the inventive concept. Referring to FIG. 15, a nonvolatile memory module 5200 may include a control circuit 5210, a nonvolatile memory device 5220, and a RAM device 5230. The control circuit 5210 may include a nonvolatile memory module controller 5211 and an SPD 5212. The nonvolatile memory module 5200 may operate to be similar to the nonvolatile memory module 4200 of FIG. 14. However, the nonvolatile memory module 5200 may not include the data buffer circuit 4213 unlike the nonvolatile memory module 4200 of FIG. 14. That is, the nonvolatile memory module 5200 of FIG. 15 may directly provide data, received from the processor 1100 through the data signal DQ and the data strobe signal DQS, to the nonvolatile memory module controller 5211 or the RAM device 5230. Alternatively, data from the nonvolatile memory module controller 5211 of the nonvolatile memory module 5200 or data from the RAM device 5230 thereof may be directly provided to the processor 1100 through the data signal DQ and the data strobe signal DQS.

The nonvolatile memory module 4200 of FIG. 14 may be a memory module of an LRDIMM shape, and the nonvolatile memory module 5200 of FIG. 15 may be a memory module of an RDIMM shape.

FIG. 16 is a diagram illustrating a server system to which a nonvolatile memory system according to an exemplary embodiment of the inventive concept is applied. Referring to FIG. 16, a server system 6000 may include a plurality of server racks 6100. Each of the server racks 6100 may include a plurality of nonvolatile memory modules 6200. The nonvolatile memory modules 6200 may be directly connected with processors respectively included in the server racks 6100. For example, the nonvolatile memory modules 6200 may have the form of a dual in-line memory module and may be mounted on a DIMM socket electrically connected with a processor so as to communicate with the processor 1100. In an exemplary embodiment, the nonvolatile memory modules 6200 may be used as storage of the server system 6000.

According to exemplary embodiments of the inventive concept, a host may perform decoding/descrambling, thereby improving the system performance.

While the inventive concept has been described with reference to exemplary embodiments, it will be apparent to those skilled in the art that various changes and modifications may be made without departing from the spirit and scope of the inventive concept. Therefore, it should be understood that the above exemplary embodiments are not limiting, but illustrative.

What is claimed is:

1. A computing system comprising:
a host;
at least one memory module connected with the host through a first channel; and
at least one nonvolatile memory module connected with the host through a second channel,
wherein the host comprises:
an encoder configured to encode packet data; and
a memory module driver configured to transfer encoded packet data to the at least one memory module and to decode the encoded packet data using a decoder table to transfer decoded packet data to the at least one nonvolatile memory module.

2. The computing system of claim 1,
wherein the host and the at least one memory module transmit/receive data with each other through a double data rate (DDR) interface, and
wherein the host and the at least one nonvolatile memory module transmit/receive data with each other through the DDR interface.

3. The computing system of claim 1, wherein the encoder performs at least one of scrambling, ECC encoding, swizzling, or randomizing with respect to the packet data.

4. The computing system of claim 1,
wherein the packet data comprises slot information indicating that the at least one memory module and the at least one nonvolatile memory module are inserted, and
wherein the memory module driver determines whether to decode the encoded packet data based upon the slot information.

5. The computing system of claim 1, wherein the decoder table is generated using initialization data transferred from the at least one nonvolatile memory module during an initialization operation of the at least one nonvolatile memory module.

6. The computing system of claim 5, wherein the initialization data is transferred to the host from the at least one nonvolatile memory module by a mode register set (MRS) mode read operation.

7. The computing system of claim 5, wherein a decoding function is generated using the decoder table.

8. The computing system of claim 1,
wherein data is updated in a predetermined order on the at least one nonvolatile memory module, and
wherein the memory module driver generates a command table by recognizing the updated data.

9. The computing system of claim 1,
wherein the at least one nonvolatile memory module comprises:
a plurality of nonvolatile memories;
a buffer memory configured to temporarily store data needed for driving; and
a nonvolatile memory module controller configured to control the plurality of nonvolatile memories and the buffer memory, and
wherein the nonvolatile memory module controller comprises a RAM which exchanges data with the host through a DDR interface.

10. The computing system of claim 1, wherein the at least one nonvolatile memory module comprises:
a plurality of nonvolatile memories;
data buffers configured to transmit/receive data with the host;
a plurality of dynamic random access memories transmitting and receiving data of the data buffers; and
a nonvolatile memory module controller configured to control the plurality of nonvolatile memories and the plurality of dynamic random access memories and to enable the host to access the plurality of nonvolatile memories.

11. The computing system of claim 1, wherein the at least one nonvolatile memory module comprises:
a plurality of nonvolatile memories;
a plurality of dynamic random access memories exchanging data with the host through a DDR interface; and
a nonvolatile memory module controller configured to control the plurality of nonvolatile memories and the plurality of dynamic random access memories and to enable the host to access the plurality of nonvolatile memories.

12. A data transfer method of a computing system which includes a host, at least one volatile memory module, and at least one nonvolatile memory module, the method comprising:
scrambling packet data;
determining whether there is a need to descramble the scrambled packet data;
descrambling the scrambled packet data using a decoder table when there is a need to descramble the scrambled packet data; and
outputting the descrambled packet data to the at least one nonvolatile memory module.

13. The method of claim 12, wherein the determining is performed based upon slot information indicating that the at least one volatile memory module or the at least one nonvolatile memory module is inserted.

14. The method of claim 12, further comprising:
outputting the scrambled packet data to the at least one volatile memory module when there is no need to descramble the scrambled packet data.

15. The method of claim 12, wherein during an initialization operation of the at least one nonvolatile memory module, the decoder table is generated by transferring predetermined data between the host and the at least one nonvolatile memory module, decoding the transferred data, and comparing the transferred data and the decoded data.

16. A data transfer method of a computing system which includes a host, at least one volatile memory module, and at least one nonvolatile memory module, the method comprising:
descrambling an address, a command, data, or a serial presence detect (SPD) command;
scrambling the descrambled address, command, data or SPD command; and
transferring the scrambled address, command, data or SPD command to the at least one volatile memory module or the at least one nonvolatile memory module.

17. The method of claim 16, wherein the scrambling comprises:
descrambling the address and the command when defining a command between the host and the at least one volatile memory module or between the host and the at least one nonvolatile memory module.

18. The method of claim 16, wherein the SPD command is transferred to the at least one volatile memory module or the at least one nonvolatile memory module through a side-band channel.

19. The method of claim 16, further comprising:
constructing the address, the command, the data, or the SPD command with a table.

20. The method of claim 16, wherein the descrambling further comprises:
changing a descramble manner so as to correspond to a scramble manner.
